(19) United States
(12) Patent Application Publication
(10) Pub. No.: US 2024/0363576 A1
(43) Pub. Date: Oct. 31, 2024

(54) SEMICONDUCTOR PACKAGE STRUCTURE AND METHOD FOR FORMING THE SAME

(71) Applicant: TAIWAN SEMICONDUCTOR MANUFACTURING COMPANY LTD., HSINCHU (TW)

(72) Inventors: WEI-YU CHOU, TAICHUNG CITY (TW); YANG-CHE CHEN, HSIN-CHU CITY (TW); YI-LUN YANG, TAOYUAN CITY (TW); TING-YUAN HUANG, YILAN COUNTY (TW); HSIANG-TAI LU, HSINCHU COUNTY (TW)

(21) Appl. No.: 18/307,002

(22) Filed: Apr. 25, 2023

(51) Int. Cl. H01L 23/00; H01L 21/56; H01L 23/31; H01L 25/00; H01L 25/16; H01L 25/18

(52) U.S. Cl. CPC H01L 24/26; H01L 21/563; H01L 23/3185; H01L 24/16; H01L 24/19; H01L 24/20; H01L 24/32; H01L 24/73; H01L 24/83; H01L 24/92; H01L 25/16; H01L 25/18; H01L 25/50; H01L 2224/16227; H01L 2224/19; H01L 2224/214; H01L 2224/215; H01L 2224/26175; H01L 2224/32225; H01L 2224/73204; H01L 2224/83855; H01L 2224/92125; H01L 2924/01013; H01L 2924/01022; H01L 2924/01029; H01L 2924/01074; H01L 2924/01079

(57) ABSTRACT

A semiconductor package structure includes a semiconductor die encapsulated in a molding compound, a redistribution structure over the semiconductor die and the molding compound, a surface device over and electrically connected to the redistribution structure, a first connector over and electrically connected to the redistribution structure, a second connector between the surface device and the redistribution structure, a trench in the redistribution structure and laterally surrounding the surface device in a top view of the semiconductor package structure, and an underfill. The second connector electrically connects the surface device to the redistribution structure. The underfill surrounds the second connector. The underfill include a first portion and a second portion. The first portion of the underfill is located between the surface device and the redistribution structure and laterally surrounding the second connector, and the second portion of the underfill is disposed in the trench.

### BACKGROUND

Integrated circuit packaging is becoming increasing complex, with more device dies incorporated in a single package to form a system having more functions. Device dies, packages, and independent passive devices (IPDs) may be incorporated in the single package to achieve the additional functionality.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1 to 8 are schematic cross-sectional partial views of various stages in a formation of a semiconductor package structure according to aspects of the present disclosure in one or more embodiments.

FIGS. 9A to 9C are schematic cross-sectional partial views in of a semiconductor package structure according to aspects of the present disclosure in one or more embodiments.

FIGS. 10A to 10C are plan views illustrating a portion of a semiconductor package structure according to aspects of the present disclosure in one or more embodiments.

FIGS. 11 and 12 are schematic cross-sectional partial views of various stages in a formation of a semiconductor package structure according to aspects of the present disclosure in one or more embodiments.

FIG. 13 is a plan view illustrating a portion of a semiconductor package structure according to aspects of the present disclosure in one or more embodiments.

FIGS. 14A and 14B are schematic cross-sectional partial views of various stages in a formation of a semiconductor package structure according to aspects of the present disclosure in one or more embodiments.

FIG. 15 is a flowchart representing a method for forming a semiconductor package structure according to aspects of the present disclosure.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper.” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, although the terms such as “first,” “second” and “third” describe various elements, components, regions, layers and/or sections, these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in the respective test measurements. Also, as used herein, the terms “substantially.” “approximately” or “about” generally mean within a value or range that can be contemplated by people having ordinary skill in the art. Alternatively, the terms “substantially,” “approximately” or “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of times, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

Integrated passive devices (IPDs) are provided and integrated into packages and 3DIC packages. In some comparative approaches, it is found that underfill materials used to secure connections between the IPDs and underlying structures may overflow a keep-out zone (KOZ). The underfill may cover adjacent connectors and thus require additional operations for removing the covered connector.

According to some embodiments, the present disclosure provides semiconductor package structures and methods of forming the semiconductor packages. In some embodiments, the semiconductor package structure includes a trench for receiving overflowing underfill materials. Due to the trench, the underfill overflow issue is mitigated.

Advantageous features of some or all of the embodiments described herein may further include a smaller area of the keep-out zone, which may enhance performance of a power distribution network (PDN). Some embodiments may provide integration of 3D stacked IPDs with InFO processes, thus making adoption of the embodiments practical. In some embodiments, 3D stacking of IPDs avoids a need to remove ball grid array (BGA) connectors from a socket landscape (e.g., a footprint of a package), resulting in improved current handling due to an increase in conductive area (e.g., through more BGA connectors) due to the smaller keep-out zone.

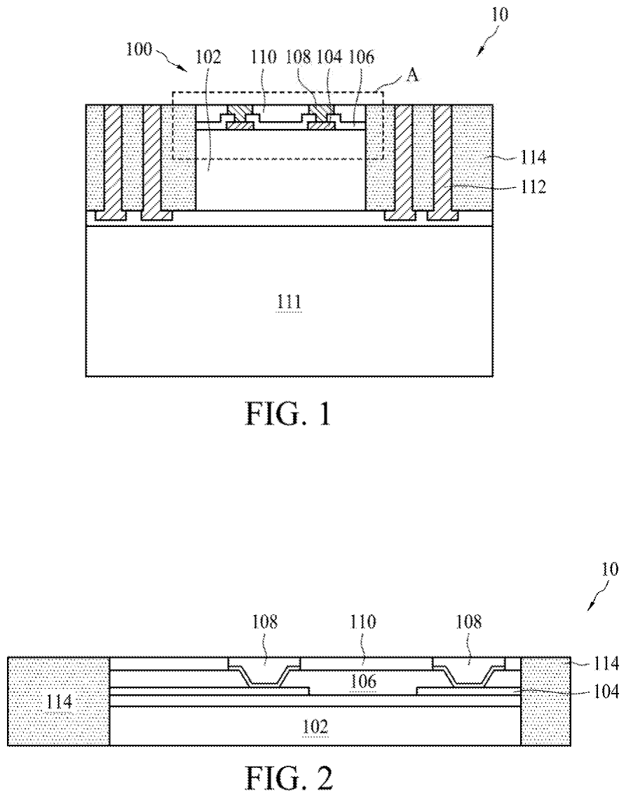

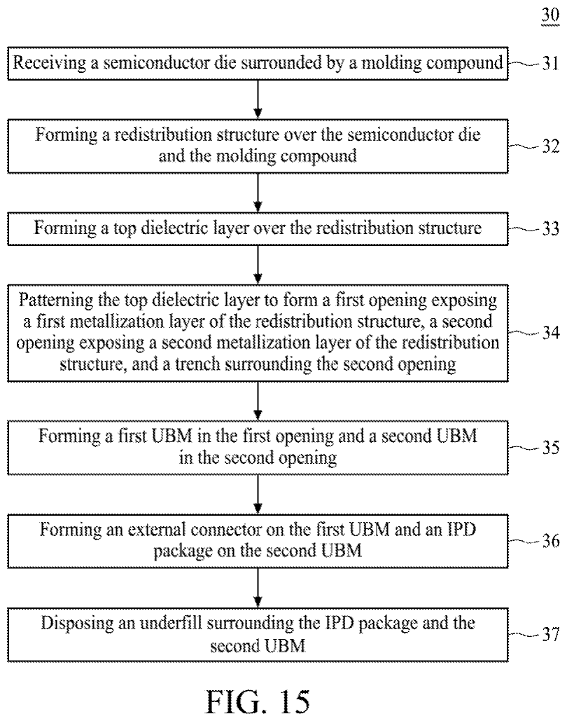

FIGS. 1 to 8 are schematic cross-sectional views of various stages in a formation of a semiconductor package structure according to aspects of the present disclosure in one or more embodiments. Further, FIGS. 2 to 8 are enlarged views of a portion A of the semiconductor package structure shown in FIG. 1. The corresponding operations are also reflected schematically in a process flow shown in FIG. 15.

Please refer to FIGS. 1 and 2. In some embodiments, the semiconductor package structure includes a semiconductor die 100. In some embodiments, more than one semiconductor dies may be provided. The semiconductor die 100 may include one or more types of chip(s) selected from digital chips, analog chips or mixed signal chips, application-specific integrated circuit (ASIC) chips, sensor chips, memory chips, logic chips, and/or other electronic devices.

In some embodiments, the semiconductor die 100 includes a semiconductor substrate 102, contact pads 104 over the semiconductor substrate 102, a passivation layer 106 over the semiconductor substrate 102 and exposing portions of the contact pads 104, die connectors 108 over the passivation layer 106 and electrically connected to the contact pads 104, and a protection layer 110 over the passivation layer 106 and aside the die connectors 108. In some embodiments, the die connectors 108 include conductive pillars or vias, solder bumps, gold bumps, copper posts, or the like, and are formed by an electroplating process or other suitable deposition process. A surface on which the die connectors 108 are distributed for further electrical connection may be referred to as an active surface of the semiconductor die 100. In some embodiments, the protection layer 110 includes polybenzoxazole (PBO), polyimide (PI), a suitable organic or inorganic material, or the like.

In some embodiments, the semiconductor die 100 is disposed or provided over a substrate 111. In some embodiments, the substrate 111 may be a temporary carrier wafer. The temporary carrier wafer 111 may be a glass carrier, a ceramic carrier, or the like. In other embodiments, the temporary carrier wafer 111 may be made of a material such as silicon, polymer, polymer composite, metal foil, ceramic, glass, glass epoxy, beryllium oxide, tape, or other material suitable for structural support. In some embodiments, a redistribution layer (RDL) (not shown) may be formed over the substrate 111 prior to the disposing of the semiconductor die 100 over the substrate 111. In some embodiments, an adhesive layer (not shown) is deposited or laminated over the substrate 111 before the RDL is formed and/or before the semiconductor die 100 is disposed. The adhesive layer may be photosensitive and may be easily detached from the substrate 111 by, e.g., shining an ultra-violet (UV) light on the substrate 111 in a subsequent carrier de-bonding process. For example, the adhesive layer may be a light-to-heat-conversion (LTHC) coating.

In some embodiments, conductive pillars 112 are formed over the substrate 111. Further, a molding compound 114 is formed over the substrate 111 to encapsulate the semiconductor die 100 and the conductive pillars 112, as shown in FIG. 1. The molding compound 114 may include, for example, an epoxy, an organic polymer, a polymer with or without a silica-based or glass filler added, or other materials. In some embodiments, the molding compound 114 includes a liquid molding compound (LMC) that is a gel type liquid when applied. The molding compound 114 may also include a liquid or solid when applied. Alternatively, the molding compound 114 may include other insulating and/or encapsulating materials. In some embodiments, the molding compound 114 is applied using a wafer level molding process. The molding compound 114 may be molded using, for example, compressive molding, transfer molding, or other methods.

Next, in some embodiments, the molding compound 114 is cured using a curing process. The curing process may comprise heating the molding compound 114 to a predetermined temperature for a predetermined period of time, using an anneal process or other heating process. The curing process may also include an ultraviolet (UV) light exposure process, an infrared (IR) energy exposure process, combinations thereof, or a combination thereof with a heating process. Alternatively, the molding compound 114 may be cured using other methods. In some embodiments, a curing process is not included.

Next, a planarization process, such as chemical and mechanical polish (CMP), may be performed to remove excess portions of the molding compound 114 to expose the semiconductor die 100. In some embodiments, the molding compound 114, the conductive pillars 112, the protection layer 110, and the die connectors 108 have a coplanar upper surface after the planarization process.

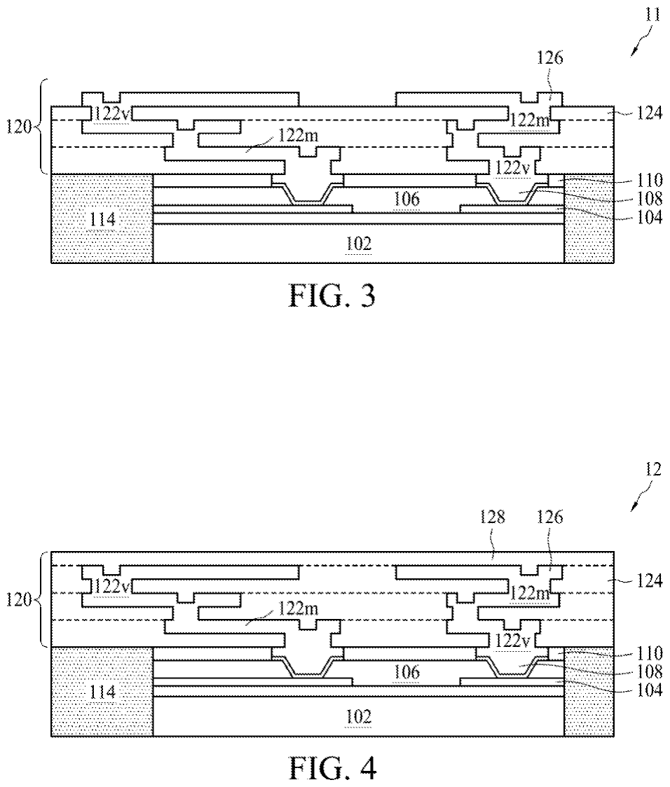

Referring to FIG. 3, in some embodiments, a redistribution structure 120 is formed over the semiconductor die 100 and the molding compound 114. The redistribution structure 120 is coupled to the die connectors 108. In some embodiments, the redistribution structure 120 may be referred to as a front side redistribution structure, but the disclosure is not limited thereto. The redistribution structure 120 includes one or more layers of metallization features (including metallization layers 122m and vias 122v) formed in one or more dielectric layer 124. In some embodiments, the one or more dielectric layers 124 are formed of a polymer, such as PBO, polyimide, BCB, or the like; a nitride such as silicon nitride; an oxide such as silicon oxide, PSG, BSG, BPSG, or the like. The one or more dielectric layers 124 may be formed by a suitable deposition process, such as spin coating, CVD, laminating, the like, or a combination thereof. In some embodiments, the metallization features of the redistribution structure 120 include the metallization layers 122m and the vias (e.g., 122v) formed of a suitable conductive material such as copper, titanium, tungsten, aluminum, or the like. The redistribution structure 120 may be formed by: forming a dielectric layer, forming openings in the dielectric layer to expose underlying metallization features, forming a seed layer (not shown) over the dielectric layer and in the openings, forming a patterned photoresist (not shown) with a designed pattern over the seed layer, plating (e.g., electroplating or electroless plating) the conductive material in the designed pattern and over the seed layer, and removing the photoresist and portions of the seed layer on which the conductive material is absent. Other methods of forming the redistribution structure 120 are also possible and are fully intended to be included within the scope of the present disclosure.

The number of the dielectric layers 124 and the number of the layers of the metallization features 122m, 122v in the redistribution structures 120 of FIG. 3 are merely non-limiting examples. Other numbers of the dielectric layers and other numbers of the layers of the metallization features are also possible and are fully intended to be included within the scope of the present disclosure.

In some embodiments, the redistribution structure 120 includes top metallization layers 126 formed over the dielectric layer 124, as shown in FIG. 3. In such embodiments, top surfaces and sidewalls of the top metallization layers 126 are exposed. The top metallization layers 126 can include conductive materials same as those of the metallization layers 122m and the vias 122v, but the disclosure is not limited thereto.

Referring to FIG. 4, the redistribution structure 120 further includes a top dielectric layer 128 formed to cover the top metallization layers 126. The top dielectric layer 128 can include dielectric materials same as those of the dielectric layer 124, but the disclosure is not limited thereto.

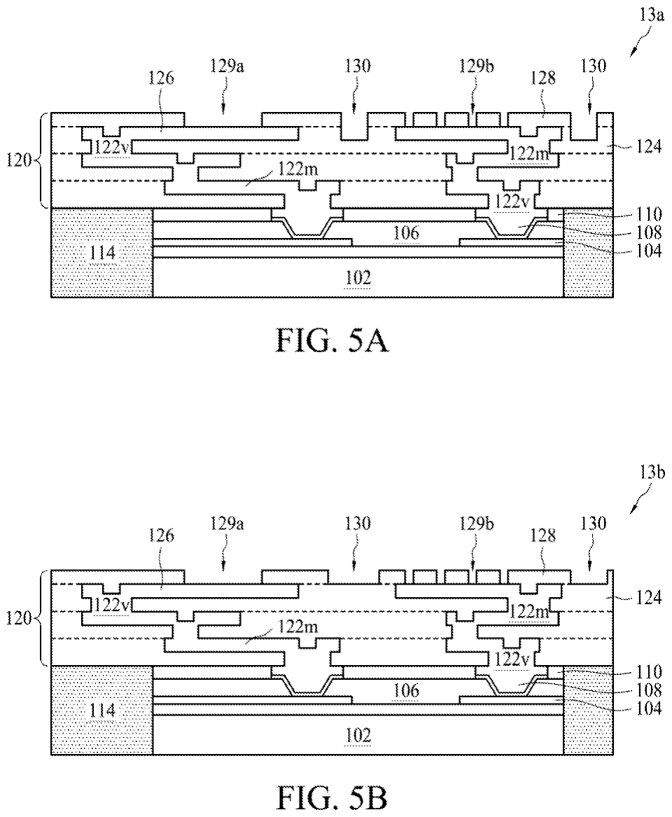

Next, referring to FIGS. 5A to 5C, in some embodiments, the top dielectric layer 128 is patterned. The patterning of the top dielectric layer 128 forms openings 129a and 129b in the redistribution structure 120 to expose portions of the top metallization layers 126. The patterning may be performed according to an acceptable process, such as by exposing the top dielectric layer 128 to light when the top dielectric layer 128 is a photo-sensitive material or by etching using, for example, an anisotropic etch. If the top dielectric layer 128 is a photosensitive material, the top dielectric layer 128 can be developed after the exposure. The openings 129a and 129b are formed to define locations where connectors are to be formed. Further, a width of the opening 129a and a width of the opening 129b are different for accommodating connectors of different sizes. For example, the opening 129a is used for connection to external connectors, while the opening 129b is used to couple to a semiconductor package having micro bumps. Therefore, the width of the opening 129a is greater than the width of the opening 129b. Further, locations of the openings 129a are separate from locations of the openings 129b.

In some embodiments, the patterning of the top dielectric layer 128 further includes formation of a trench 130 to surround the openings 129b. That is, the trench 130 is formed in the redistribution structure 120 to separate the openings 129b from the openings 129a, as shown in FIGS. 5A to 5C. In some embodiments, a distance between the opening 129a and the trench 130 is greater than a distance between the opening 129b and the trench 130, but the disclosure is not limited thereto. In contrast to the openings 129a and 129b, which have the top dielectric layer 128 as sidewalls and the top metallization layers 126 as bottoms, the trench 130 has the top dielectric layer 128 as sidewalls and the dielectric layer 124 as sidewalls and bottoms. In some embodiments, a bottom surface of the trench 130 may be aligned (i.e., coplanar) with a bottom surface of the top metallization layer 126 or higher than the bottom surface of the top metallization layer 126, as shown in FIG. 5A. In other embodiments, the bottom surface of the trench 130 may be lower than a top surface of the top dielectric layer 128 and aligned with a top surface of the top metallization layer 126, as shown in FIG. 5B, but the disclosure is not limited thereto. In some embodiments, as shown in FIG. 5C, a plurality of trenches 1301 and 1302 may be formed in the redistribution structure 120. The trenches 1301 and 1302 may have a concentric configuration. For example, the trench 1301 laterally surrounds the openings 129b, and the trench 1302 laterally surrounds the openings 129b and the trench 1301, as shown in FIG. 5C.

A width of the trenches 130, 1301 and 1302 may be different from the widths of the openings 129a and the widths of the openings 129b. In some embodiments, the widths of the trenches 130, 1301 and 1302 may be less than the widths of the openings 129a. In some embodiments, the widths of the openings 130, 1301 and 1302 may be greater than the widths of the openings 129b. In some embodiments, the widths of the trenches 130, 1301 and 1302 may be between approximately 5 micrometers and approximately 30 micrometers, but the disclosure is not limited thereto. In some embodiments, a depth of the trenches 130, 1301 and 1302 are equal to or greater than a thickness of the top dielectric layer 128. In some embodiments, the depth of the trenches 130, 1301 and 1302 are in a range from approximately 5 micrometers to approximately 20 micrometers, but the disclosure is not limited thereto. As shown in FIGS. 5A to 5C, it may be concluded that the amount, the widths and the depths of the trenches 130 may vary depending on different product or process designs; however, a volume of the trench 130 (i.e., a sum of volumes of 1301 and 1302) may be similar. In some embodiments, the volume of the trench 130 may be modified according to various process designs.

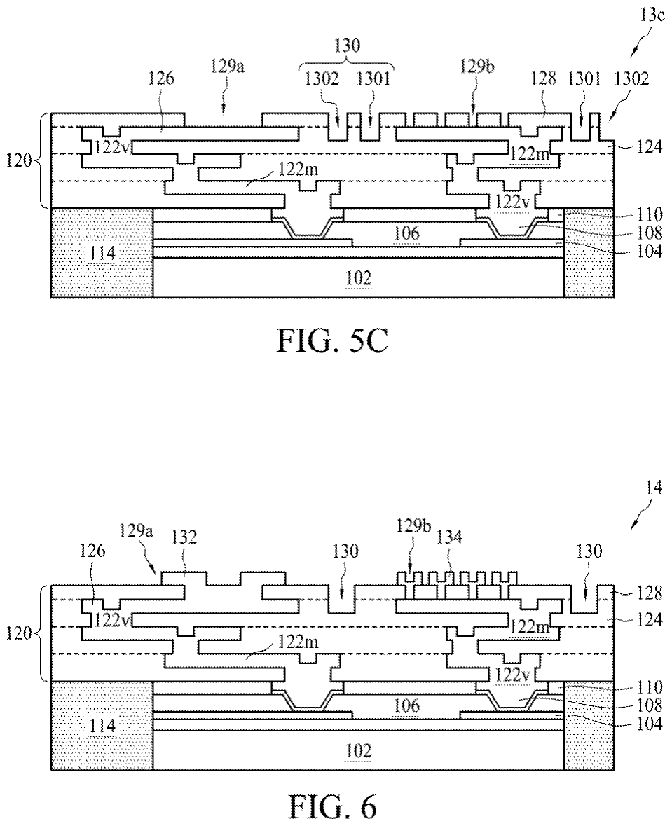

Referring to FIG. 6, metal layers 132 and 134 are formed on an exterior side of the redistribution structure 120. The metal layers 132 function to couple to the top metallization layer 126 exposed through the openings 129a, and may be referred to as under bump metallurgies (UBMs). The metal layers 134 function to couple to the top metallization layer 126 exposed though the openings 129b. Further, the metal layers 134 function to couple to a semiconductor package having micro bumps, and may be referred to as micro bump pads. In some embodiments, the metal layers 132 are formed at different times and by processes different from those of the metal layers 134. In other alternative embodiments, the metal layer 132 are formed at a same time and by same processes as the processes of the metal layers 134.

In the illustrated embodiment, the metal layer 132 is formed in the opening 129a, and the metal layers 134 are formed in the openings 129b to couple to the top metallization layer 126, respectively. The formation of the metal layers 132 and 134 can include, for example, formation of a seed layer (not shown) over the top dielectric layer 128. In some embodiments, the seed layer is a metal layer, which may be a single layer or a composite layer including a plurality of sub-layers formed of different materials. In some embodiments, the seed layer includes a titanium layer and a copper layer over the titanium layer. The seed layer may be formed using, for example, PVD or the like. A photo resist is then formed and patterned on the seed layer. The photo resist may be formed by spin coating or the like and may be exposed to light for patterning. A pattern of the photoresist corresponds to the metal layers 132 and 134. The patterning forms openings through the photoresist in order to expose the seed layer. A conductive material is formed in the openings of the photo resist and on exposed portions of the seed layer. The conductive material may be formed by plating, such as electroplating or electroless plating, or the like. The conductive material may comprise a metal, such as copper, titanium, tungsten, aluminum, or the like. Next, the photo resist and portions of the seed layer on which the conductive material is absent are removed. The photo resist may be removed by an acceptable ashing or stripping process, such as using an oxygen plasma or the like. Once the photo resist is removed, exposed portions of the seed layer are removed, such as by using an acceptable etching process, for example wet or dry etching. Remaining portions of the seed layer and the conductive material form the metal layers 132 and 134. In the embodiment, where the metal layer 132 and the metal layers 134 are formed differently, additional photoresist and patterning steps may be utilized. In contrast to the openings 129a and 129b, where the metal layers 132 and 134 are formed, the trench 130 is free of the conductive materials (i.e., the seed layer and the metal layer).

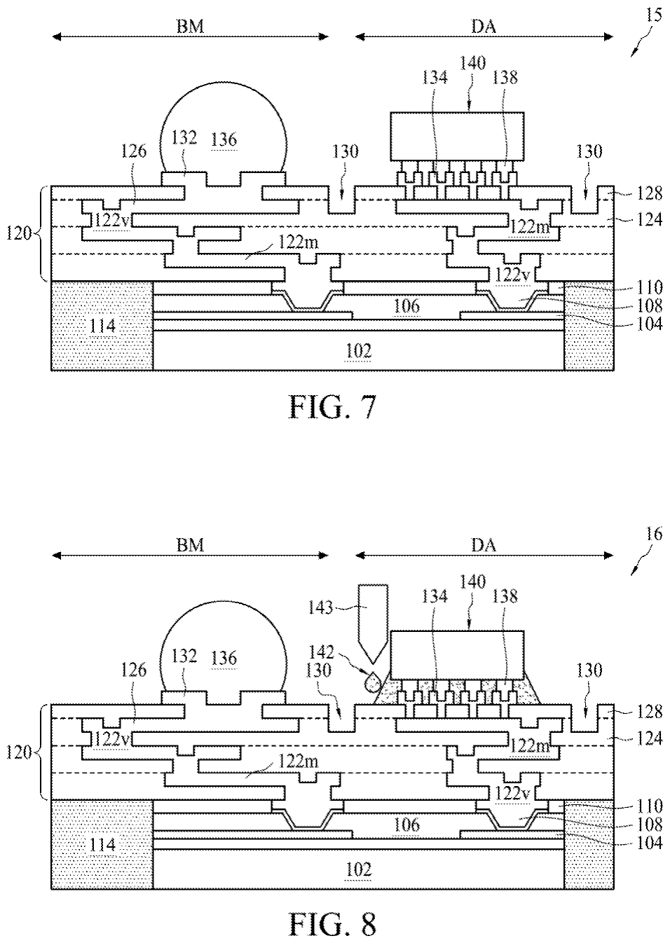

Referring to FIG. 7, a connector 136 is formed on the metal layer 132. The connector 136 is electrically connected to the redistribution structure 120 through the metal layer 132. In some embodiments, the connector 136 serves as an external connector, but the disclosure is not limited thereto. The connector 136 may be a ball grid array (BGA) connector, a solder ball, a metal pillar, a controlled collapse chip connection (C4) bump, a micro bump, an electroless nickel-electroless palladium-immersion gold technique (ENEPIG) formed bump, or the like. The connector 136 may include a conductive material such as solder, copper, aluminum, gold, nickel, silver, palladium, tin, the like, or a combination thereof. In some embodiments, the connector 136 is formed by initially forming a layer of solder through commonly used methods such as evaporation, electroplating, printing, solder transfer, ball placement, or the like. Once a layer of solder has been formed on the structure, a reflow may be performed in order to shape the solder into the desired bump shapes. In another embodiment, the connector 136 is a metal pillar (such as a copper pillar) formed by sputtering, printing, electro plating, electroless plating, CVD, or the like. The metal pillar may be solder free and have substantially vertical sidewalls. In some embodiments, a metal cap layer (not shown) is formed on a top of the metal connector 136. The metal cap layer may include nickel, tin, tin-lead, gold, silver, palladium, indium, nickel-palladium-gold, nickel-gold, the like, or a combination thereof. The metal cap layer may be formed by a plating process.

In some embodiments, a surface device 140 is disposed over the metal layers 134. The surface device 140 may be a semiconductor device such as an integrated passive device (IPD) package. A wide variety of IPD packages, such as baluns, couplers, splitters, filters and diplexers can be integrated in the IPD package 140. The IPD package 140 may replace traditional discrete surface mount devices (SMDs) for smaller footprint, cost reduction, and performance improvement. In some embodiments, other types of metal layers 134 and other types of semiconductor devices or packages are also contemplated within the scope of the present disclosure. The IPD package 140 is bonded to the metal layer 134 by connectors 138 such as joints or micro bumps. The connectors 138 further electrically connect the IPD package 140 to the redistribution structure 120.

Still referring to FIG. 7, a ball/bump mounting zone BM and a die/device attachment zone DA are defined. In some embodiments, the ball/bump mounting zone BM may be designated for mounting external connectors such as conductive bumps, BGA balls, or solder balls, while the die/device attachment zone DA may be designated for mounting one or more semiconductor dies. In some comparative approaches, a keep-out zone KOZ is interposed between the die/device attachment zone DA and the ball/bump mounting zone BM. In contrast to such comparative approaches, the keep-out zone is no longer required in the present disclosure. In place of the keep-out zone, the trench 130 is provided to separate the ball/bump mounting zone BM and the die/device attachment zone DA.

Referring to FIG. 8, an underfill 142 is dispensed between the IPD package 140 and the redistribution structure 120. The underfill 142 further surrounds and is in contact with the connectors 138. The underfill 142 is provided to help protect and isolate the IPD package 140 that has been bonded. In some embodiments, the underfill 142 is a protective material used to cushion and support the IPD package 140 from operational and environmental degradation, such as stresses caused by heat generated during operation. The underfill 142 may include, for example but not limited thereto, a liquid epoxy or other protective material, which is then cured to harden.

In some embodiments the underfill 142 is dispensed between the IPD package 140 and the redistribution structure 120 by an injection 143. As shown in FIG. 8, the underfill 142 flows between the IPD package 140, the connectors 138, the metal layers 134 and the top dielectric layer 128 of the redistribution structure 120 in the die/device attachment zone DA. In some embodiments, the underfill 142 may cover a portion of sidewalls of the IPD package 140, as shown in FIG. 8. Further, some amount of the underfill 142 may overflow outside of the die/device attachment zone DA.

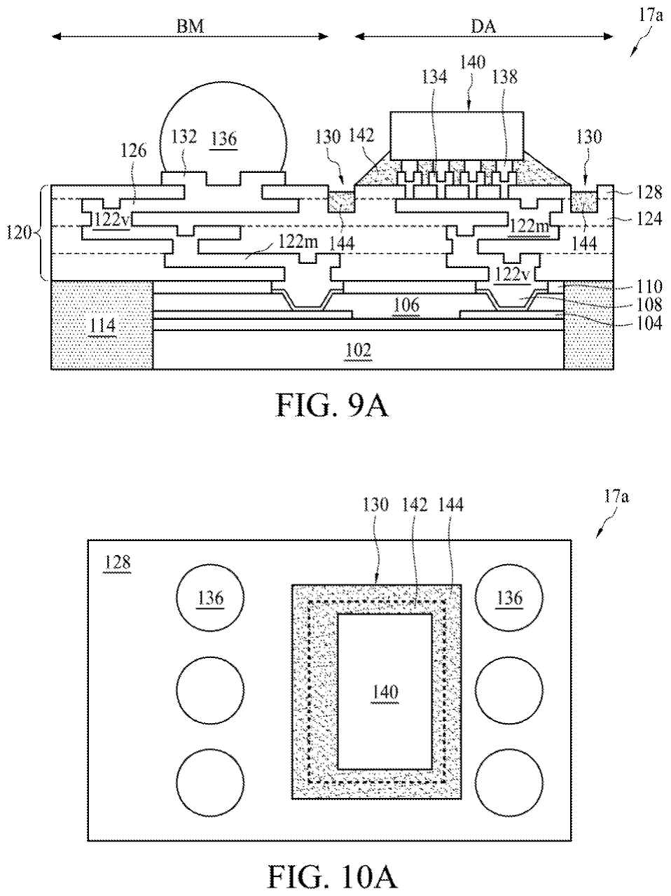

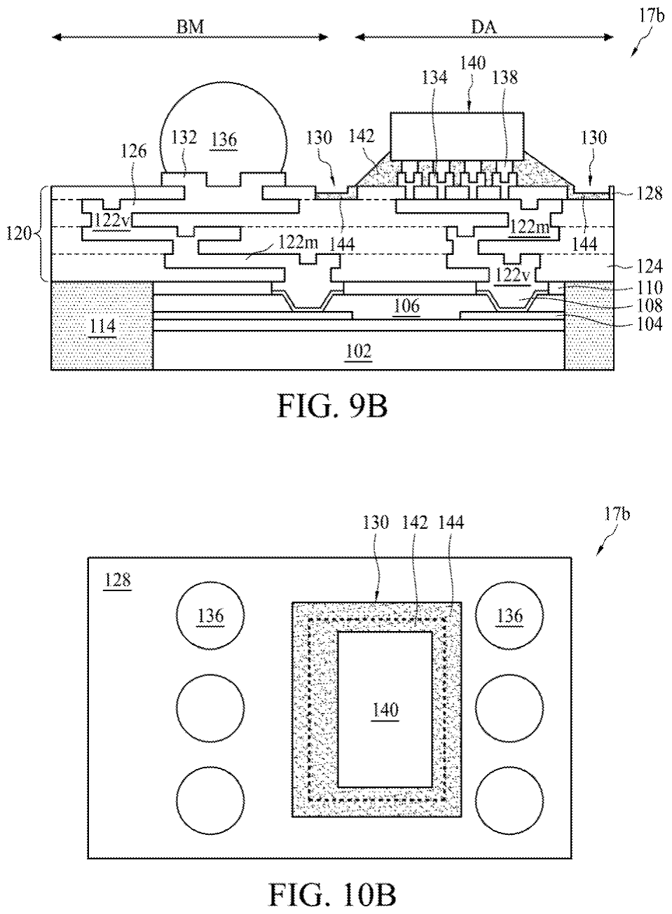

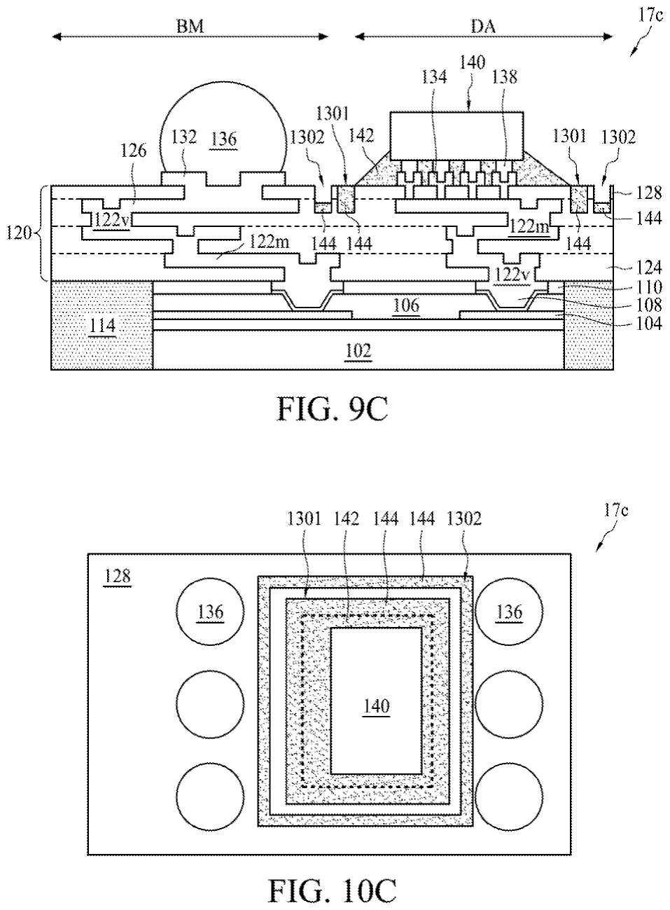

Referring to FIGS. 9A and 10A, FIGS. 9B and 10B, and FIGS. 9C and 10C, in some embodiments, a portion 144 of the underfill 142 may overflow into the trench 130. In other words, some excess or superfluous underfill 144 may be accommodated in the trench 130. Accordingly, an overflowed portion 144 of the underfill 142 may be kept out of the ball/bump mounting zone BM. Thus, the overflow issue in the ball/bump mounting zone BM is mitigated.

In some embodiments, a top surface of the overflow portion 144 of the underfill 142 may be aligned with or lower than a top surface of the redistribution structure 120 (i.e., a top surface of the top dielectric layer 128), depending on a volume of the overflow portion 144. A bottom surface of the overflow portion 144 is substantially leveled with the bottom surface of the top metallization layer 126, as shown in FIG. 9A.

Referring to FIGS. 9B and 10B, in some embodiments, the bottom surface of the overflow portion 144 is substantially leveled with the top surface of the top metallization layer 126, as shown in FIG. 9B. In some embodiments, the overflow portion 144 may couple to the underfill 142, but the disclosure is not limited thereto.

Referring to FIG. 9C, in some embodiments, the trenches 1301 and 1302 provide dual protections. For example, the overflow portion 144 may fill the trench 1301, while the trench 1302 is free of the underfill 142. In other embodiments, the overflow portion 144 may overflow into the trench 1302 and fill the trench 1302, as shown in FIG. 9C. In still other embodiments, the overflow portion 144 may fill both of the trenches 1301 and 1302, though not shown.

Accordingly, the trench 130 stops the movement of the underfill 142 toward the connector 136. In other words, the trench 130 prevents the underfill 142 from coming into contact with the adjacent connector 136. Accordingly, possibility of contamination through physical contact is reduced.

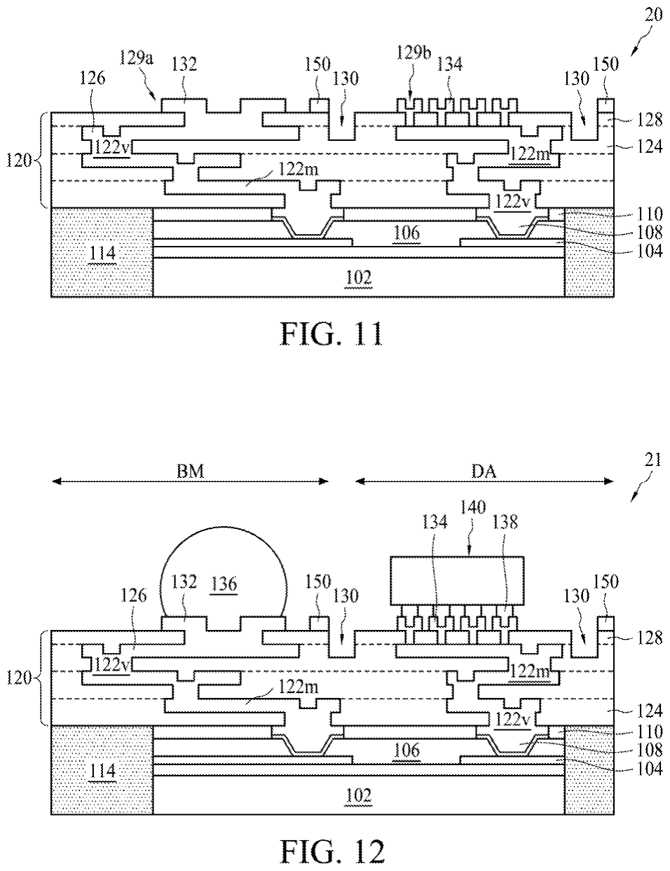

Please refer to FIGS. 11 to 14B, which are schematic cross-sectional partial views of various stages in a formation of a semiconductor package structure according to aspects of the present disclosure in one or more embodiments. It should be noted that same elements in FIGS. 1 to 10C and FIGS. 11 to 14B are designated by same numerals, and may include same materials; therefore, repeated descriptions are omitted for brevity.

In some embodiments, during the forming of the metal layers 132 and 134, a wall structure 150 may be formed over the top dielectric layer 128. The wall structure 150 includes a conductive material, but the disclosure is not limited thereto. In some embodiments, the wall structure 150 may include a conductive material same as that of the metal layers 132 and 134. In some embodiments, a thickness or a height of the wall structure 150 is equal to a thickness or a height of the metal layers 132 and 134, but the disclosure is not limited thereto. In some embodiments, the wall structure 150 laterally surrounds the trench 130 and the metal layers 134. The wall structure 150 further separates the trench 130 from the metal layers 132. In some embodiments, a sidewall of the wall structure 150 may be aligned with a sidewall of the trench 130, but the disclosure is not limited thereto. For example, in other embodiments, the wall structure 150 may be separated from the trench 130, though not shown.

Referring to FIG. 12, in some embodiments, the connector 136 is formed on the metal layer 132. In some embodiments, the connector 136 serves as an external connector, but the disclosure is not limited thereto. As mentioned above, the connector 136 may be a BGA connector, a solder ball, a metal pillar, a C4 bump, a micro bump, an ENEPIG formed bump, or the like. The surface device 140 is disposed over the metal layers 134. The surface device 140 may be a semiconductor device such as an integrated passive device (IPD) package. A wide variety of IPD packages, such as baluns, couplers, splitters, filters and diplexers can be integrated in the IPD package 140. The IPD package 140 may replace traditional discrete surface mount devices (SMDs) for smaller footprint, cost reduction, and performance improvement. In some embodiments, other types of metal layers 134 and other types of semiconductor devices or packages are also contemplated within the scope of the present disclosure. The IPD package 140 is bonded to the metal layer 134 by connectors 138 such as joints or micro bumps.

Further, a ball/bump mounting zone BM and a die/device attachment zone DA are defined. In some embodiments, the ball/bump mounting zone BM may be designated for mounting external connectors such as conductive bumps, BGA balls, or solder balls, while the die/device attachment zone DA may be designated for mounting one or more semiconductor dies. As shown in FIG. 12, the wall structure 150 and the trench 130 are provided to separate the ball/bump mounting zone BM from the die/device attachment zone DA.

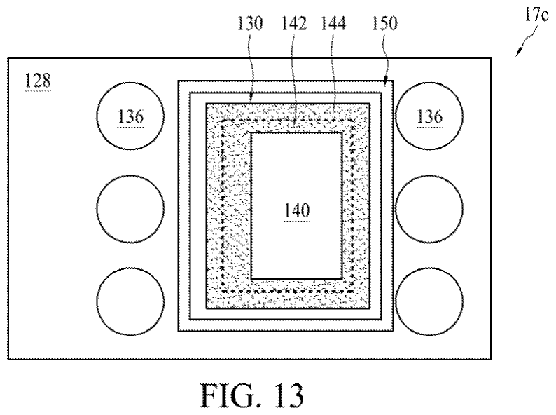

Referring to FIG. 13, the underfill 142 is dispensed between the IPD package 140 and the redistribution structure 120. The underfill 142 is provided to help protect and isolate the IPD package 140 that has been bonded. In some embodiments, the underfill 142 is a protective material used to cushion and support the IPD package 140 from operational and environmental degradation, such as stresses caused by heat generated during operation.

As shown in FIG. 13, in some embodiments, the underfill 142 flows between the IPD package 140, the connectors 138, the metal layers 134 and the top dielectric layer 128 of the redistribution structure 120. In some embodiments, the underfill 142 may cover a portion of sidewalls of the IPD package 140, as shown in FIG. 13. Further, some amount of the underfill 142 may overflow outside of the die/device attachment zone DA.

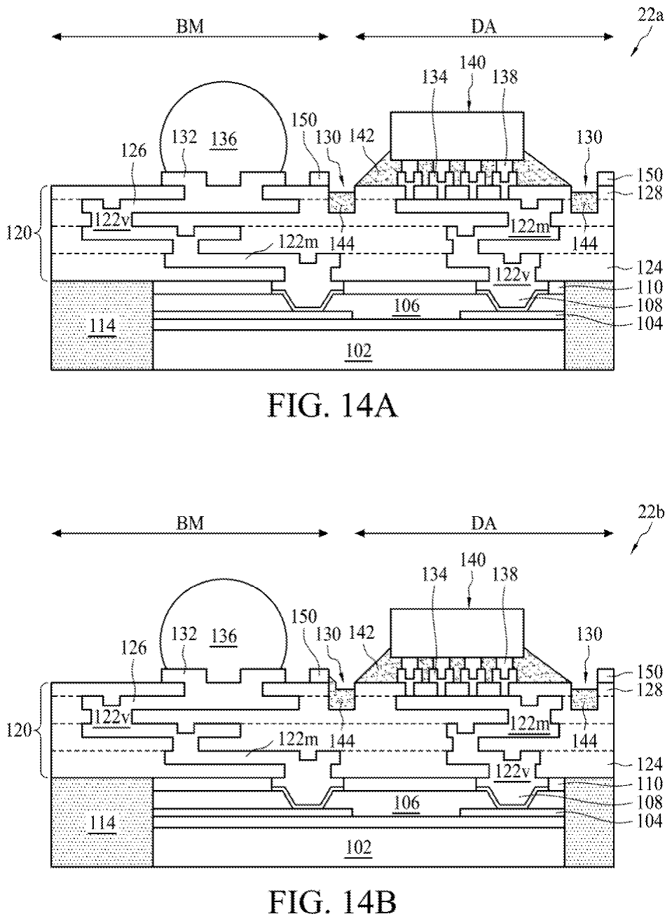

In some embodiments, the overflow portion 144 may fill the trench 130. The top surface of the overflow portion 144 may be aligned with or lower than the top surface of the redistribution structure 120 (i.e., the top surface of the top dielectric layer 128), depending on a volume of the overflow portion 144. The bottom surface of the overflow portion 144 is aligned with the bottom surface of the top metallization layer 126, as shown in FIG. 14A.

In some embodiments, the overflow portion 144 may be in contact with the wall structure 150, as shown in FIG. 14B. In such embodiments, although a volume of the trench 130 is insufficient to accommodate the overflow portion 144, the overflow portion 144 is nonetheless obstructed from the ball/bump mounting zone BM and the connector 136 by the wall structure 150. In other words, the trench 130 and the wall structure 150 work together to prevent the overflow issue.

Referring to FIG. 15, a method for forming a semiconductor package structure 30 is provided. While the disclosed method 30 is illustrated and described herein as a series of acts or operations, it will be appreciated that an order of the illustrated acts or operations is not to be interpreted in a limiting sense. For example, some operations may occur in different orders and/or concurrently with other acts or operations apart from those illustrated and/or described herein. In addition, not all illustrated operations may be required to implement one or more aspects or embodiments of the description herein. Further, one or more of the operations depicted herein may be carried out in one or more separate operations and/or phases.

In operation 31, a semiconductor die 100 is received over a carrier wafer 111. FIG. 1 illustrates a cross-sectional view of the intermediate semiconductor package structure 10 according to some embodiments corresponding to operation 31, and FIG. 2 is a partially enlarged cross-sectional view of the intermediate semiconductor package structure 10. Further, the semiconductor die 100 is surrounded or encapsulated by a molding compound 114. In some embodiments, a conductive pillar 112 may be formed in the molding compound, as shown in FIG. 1, but the disclosure is not limited thereto.

In operation 32, a redistribution structure 120 is formed over the semiconductor die 100 and the molding compound 114. FIGS. 3 and 11 illustrate cross-sectional views of the intermediate semiconductor package structures 11 and 20 according to some embodiments corresponding to operation 32. The redistribution structure 120 includes metallization features such as metallization layers 122m and vias 122v disposed in a dielectric layer 124. In some embodiments, top metallization layers 126 may be exposed as shown in FIGS. 3 and 11.

In operation 33, a top dielectric layer 128 is formed over the redistribution structure 120. FIGS. 4 and 11 illustrate cross-sectional views of an intermediate semiconductor package structures 12 and 20 according to some embodiments corresponding to operation 33.

In operation 34, the top dielectric layer 128 is patterned. FIGS. 5A to 5C and FIG. 11 respectively illustrate cross-sectional views of intermediate semiconductor package structures 13a to 13c and 20 according to some embodiments corresponding to operation 34. The patterning of the top dielectric layer 128 includes forming a first opening 129a exposing a portion of the top metallization layer 126, and a second opening 129b exposing a portion of another top metallization layer 126. In some embodiments, a width of the first opening 129a is greater than a width of the second opening 129b. Further, a trench 130 is formed in the redistribution structure 120. The trench 130 is separated from any top metallization layers 126 or metallization layers 122m of the redistribution structure 120. Further, the trench 130 surrounds the second opening 129b, and separates the first opening 129a from the second opening 129b. As shown in FIG. 5A, a bottom surface of the trench 130 may be aligned with a bottom surface of the top metallization layer 126. As shown in FIG. 5B, the bottom surface of the trench 130 may be aligned with a top surface of the top metallization layer 126. As shown in FIG. 5C, a plurality of trenches 1301 and 1302 may be formed.

In operation 35, UBMs are formed in the openings 129a and 129b. FIGS. 6 and 11 illustrate cross-sectional views of intermediate semiconductor package structures 14 and 20 according to some embodiments corresponding to operation 35. As shown in FIG. 6, a first UBM 132 is formed in the first opening 129a and coupled to the top metallization layer 126, and a second UBM 134 is formed in the second opening 129b and coupled to the top metallization layer 126. In some embodiments, a wall structure 150 may be formed simultaneously with the forming of the first and second UBMs 132 and 134.

In operation 36, an external connector 136 is formed on the first UBM 132 and an IPD package 140 is disposed on the second UBM 134. FIGS. 7 and 12 illustrate cross-sectional views of intermediate semiconductor package structures 15 and 21 according to some embodiments corresponding to operation 36. The external connector 136 may be a ball grid array (BGA) connector, a solder ball, a metal pillar, a controlled collapse chip connection (C4) bump, a micro bump, an electroless nickel-electroless palladium-immersion gold technique (ENEPIG) formed bump, or the like. A surface device such as the IPD package 140 is disposed over and bonded to the redistribution structure 120 through the second UBM 134. A wide variety of IPD packages, such as baluns, couplers, splitters, filters and diplexers, can be integrated in the IPD package 140. The IPD package 140 may replace traditional discrete surface mount devices (SMDs) for smaller footprint, cost reduction, and performance improvement. In some embodiments, w other types of metal layers and other types of semiconductor devices or packages are also contemplated within the scope of the present disclosure. The IPD package 140 is bonded to the second UBM 134 by connectors 138 such as joints or micro bumps. As shown in FIGS. 7 and 12, a height of the IPD package 140 may be less than a height of the external connector 136. Further, a ball/bump mounting zone BM and a die/device attachment zone DA are defined. The ball/bump mounting zone BM may be designated for mounting external connectors such as conductive bumps, BGA balls, or solder balls, while the die/device attachment zone DA may be designated for mounting one or more semiconductor dies. The trench 130 and the wall structure 150 surround the die/device attachment zone DA, and separate the ball/bump mounting zone BM from the die/device attachment zone DA.

In operation 37, an underfill 142 is disposed to surround the IPD package 140 and the second UBM 134. FIG. 8 illustrates a cross-sectional view of an intermediate semiconductor package structure 16 according to some embodiments corresponding to operation 27. The underfill 142 is provided to help protect and isolate the IPD package 140 that has been bonded. In some embodiments, the underfill 142 is a protective material used to cushion and support the IPD package 140 from operational and environmental degradation, such as stresses caused by heat generated during operation. The underfill 142 is dispensed between the IPD package 140 and the redistribution structure 120 by an injection 143. As shown in FIG. 8, the underfill flows between the IPD package 140, the connectors 138, the metal layers 134, and the top dielectric layer 128 of the redistribution structure 120. In some embodiments, the underfill 142 may cover a portion of sidewalls of the IPD package 140, as shown in FIG. 8. Further, some amount of the underfill 142 may overflow outside of the die/device attachment zone DA.

Please refer to FIGS. 9A and 10A, FIGS. 9B and 10B, FIGS. 9C and 10C, and FIGS. 14A and 14B, which illustrate cross-sectional views of intermediate semiconductor package structures 17a to 17c and 22a and 22b according to some embodiments corresponding to operation 37. In some embodiments, a portion 144 of the underfill 142 may overflow into the trench 130. In other words, some excess or superfluous underfill 144 may be accommodated in the trench 130. Accordingly, overflow issue, is mitigated. In some embodiments, the trench 130 stops movement of the underfill 142 toward the external connector 136. In other words, the trench 130 prevents the underfill 142 from coming into contact with the adjacent external connector 136. Accordingly, possibility of contamination through physical contact is reduced.

According to some embodiments, the present disclosure provides semiconductor package structures and methods of forming the semiconductor packages. In some embodiments, the semiconductor package structure includes a trench for receiving overflowing underfill materials. Due to the trench, the underfill overflow issue is mitigated.

In some embodiments, a semiconductor package structure is provided. The semiconductor package structure includes a semiconductor die encapsulated in a molding compound, a redistribution structure over the semiconductor die and the molding compound, a surface device over and electrically connected to the redistribution structure, a first connector over and electrically connected to the redistribution structure, a second connector between the surface device and the redistribution structure, a trench in the redistribution structure and laterally surrounding the surface device in a top view of the semiconductor package structure. and an underfill. The second connector electrically connects the surface device to the redistribution structure. The underfill surrounds the second connector. The underfill include a first portion and a second portion. The first portion of the underfill is located between the surface device and the redistribution structure and laterally surrounding the second connector, and the second portion of the underfill is disposed in the trench.

In some embodiments, a semiconductor package structure is provided. The semiconductor package structure includes a semiconductor die, a molding compound surrounding the semiconductor die, a redistribution structure over the semiconductor die and the molding compound, an integrated passive device (IPD) package over and electrically connected to the redistribution structure, an underfill between the IPD package and the redistribution structure, and a first trench in the redistribution structure. The first trench laterally surrounds the IPD package in a top view of the semiconductor package structure.

In some embodiments, a method for forming a semiconductor package structure is provided. The method includes following operations. A semiconductor die surrounded by a molding compound is received. A redistribution structure is formed over the semiconductor die and the molding compound. A top dielectric layer is formed over the redistribution structure. The top dielectric layer is patterned to form a first opening, a second opening and a trench. The first opening is formed to expose a first metallization layer of the redistribution structure, the second opening is formed to expose a second metallization layer of the redistribution structure, and the trench surrounds the second opening. A first UBM is formed in the first opening, and a second UBM is formed in the second opening. An external connector is formed on the first UBM and an IPD package is disposed on the second UBM. An underfill is disposed to surround the IPD package and the second UBM.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package structure comprising:
a semiconductor die encapsulated in a molding compound;
a redistribution structure over the semiconductor die and the molding compound;
a surface device over and electrically connected to the redistribution structure;
a first connector over and electrically connected to the redistribution structure;
a second connector between the surface device and the redistribution structure, wherein the second connector electrically connects the surface device to the redistribution structure;
a trench in the redistribution structure and laterally surrounding the surface device in a top view of the semiconductor package structure; and
an underfill, wherein a first portion of the underfill is located between the surface device and the redistribution structure and laterally surrounding the second connector, and a second portion of the underfill is disposed in the trench.

2. The semiconductor package structure of claim 1, wherein the redistribution structure comprises:
a top metallization layer; and
a top dielectric layer over the top metallization layer.

3. The semiconductor package structure of claim 2, wherein a top surface of the second portion of the underfill in the trench is substantially leveled with or lower than a top surface of the top dielectric layer.

4. The semiconductor package structure of claim 2, wherein a bottom of the trench is substantially leveled with a bottom surface of the top metallization layer.

5. The semiconductor package structure of claim 2, wherein a bottom surface of the trench is substantially leveled with a top surface of the top metallization layer.

6. The semiconductor package structure of claim 2, wherein the underfill covers a portion of the top dielectric layer.

7. The semiconductor package structure of claim 1, further comprising:
a first under ball metallization (UBM) electrically connecting the first connector to the redistribution structure; and
a second UBM electrically connecting the second connector to the redistribution structure.

8. The semiconductor package structure of claim 1, further comprising a conductive wall structure laterally surrounding the trench, wherein the trench is between the conductive wall structure and the surface device in the top view of the semiconductor package structure.

9. The semiconductor package structure of claim 7, wherein the conductive wall structure is separated from the trench.

10. The semiconductor package structure of claim 7, wherein a sidewall of the conductive wall structure is substantially aligned with a sidewall of the trench.

11. A semiconductor package structure comprising:
a semiconductor die;
a molding compound surrounding the semiconductor die;
a redistribution structure over the semiconductor die and the molding compound;
an integrated passive device (IPD) package over and electrically connected to the redistribution structure;
an underfill between the IPD package and the redistribution structure; and
a first trench in the redistribution structure, wherein the first trench laterally surrounds the IPD package in a top view of the semiconductor package structure.

12. The semiconductor package structure of claim 11, wherein a portion of the underfill is disposed in the first trench.

13. The semiconductor package structure of claim 11, further comprising a second trench in the redistribution structure, wherein the second trench laterally surrounds the IPD package and the first trench in the top view of the semiconductor package structure.

14. The semiconductor package structure of claim 11, further comprising a wall structure laterally surrounding the first trench and the IPD package in the top view of the semiconductor package structure.

15. The semiconductor package structure of claim 14, wherein the wall structure comprises a conductive material.

16. The semiconductor package structure of claim 11, further comprising at least an external connector disposed and electrically connected to the redistribution structure, wherein the first trench is between the external connector and the IPD package.

17. A method for forming a semiconductor package structure, comprising:
receiving a semiconductor die surrounded by a molding compound;
forming a redistribution structure over the semiconductor die and the molding compound;
forming a top dielectric layer over the redistribution structure;
patterning the top dielectric layer to form a first opening exposing a first metallization layer of the redistribution structure, a second opening exposing a second metallization layer of the redistribution structure, and a trench surrounding the second opening;
forming a first UBM in the first opening and a second UBM in the second opening;
forming an external connector on the first UBM and disposing an IPD package on the second UBM; and
disposing an underfill surrounding the IPD package and the second UBM.

18. The method of claim 17, wherein the underfill overflows into the trench.

19. The method of claim 17, further comprising forming a conductive wall structure surrounding the trench.

20. The method of claim 17, wherein a width of the trench, a width of the first opening and a width of the second opening are different from each other.
